(19) United States
(12) Patent Application Publication
(10) Pub. No.: US 2008/0138509 A1
(43) Pub. Date: Jun. 12, 2008

(54) Magnetic sensor and manufacturing method therefor

(75) Inventor: Satoshi Hibino, Hamakita-Shi (JP)

Correspondence Address: DICKSTEIN SHAPIRO LLP, 1177 AVENUE OF THE AMERICAS (6TH AVENUE), NEW YORK, NY, 10036-2714, US

(73) Assignee: YAMAHA CORPORATION, Hamamatsu-Shi (JP)

(21) Appl. No.: 11/878,608

(22) Filed: Jul. 25, 2007

Related U.S. Application Data
(62) Division of application No. 10/936,748, filed on Sep. 9, 2004.

(30) Foreign Application Priority Data
Sep. 11, 2003 (JP) 2003-320089

(51) Int. Cl. B05D 5/12; C23C 14/34

(52) U.S. Cl. 427/131; 204/192.12

(57) ABSTRACT

A magnetic sensor comprises a spin-valve type magnetoresistive element arranged on a substrate, wherein a bias magnetic layer made of a permanent magnet film is connected with both ends of the magnetoresistive element so as to detect the magnitude of a magnetic field. The bias magnetic layer is formed on an embedded layer made of a non-magnetic material, which comprises a thick first layer and a thin second layer that are sequentially formed and laminated together. The bias magnetic layer is composed of a CoCrPt alloy, and the thickness thereof ranges from 800 Å to 900 Å; the embedded layer is composed of Cr or a Cr alloy; the thickness of the first layer ranges from 2 nm to 10 nm. Thus, it is possible to freely set the combination of the coercive force and residual magnetism in the bias magnetic layer without changing the composition of a target.

### CROSS-REFERENCE TO RELATED APPLICATIONS

This application is divisional of U.S. patent application Ser. No. 10/936,748, filed Sep. 9, 2004, which claims priority to Japanese Patent Application Serial No. 2003-320089, filed Sep. 11, 2003, the entirety of which are incorporated herein by reference.

### BACKGROUND OF THE INVENTION

1. Field of the Invention

This invention relates to magnetic sensors of the spin-valve type using giant magnetoresistive elements (or GMR elements) and manufacturing methods therefor.

This application claims priority on Japanese Patent Application No. 2003-320089, the content of which is incorporated herein by reference.

2. Description of the Related Art

Conventionally, various types of magnetic sensors using magnetoresistive elements such as giant magnetoresistive elements (or GMR elements) have been developed and put into practical uses.

FIG. 8 is a cross-sectional view diagrammatically showing the constitution of a magnetic sensor that is conventionally known. That is, a magnetic sensor 100 comprises a spin-valve type GMR element 57 that is arranged on a substrate 50, wherein bias magnetic layers 52 made of permanent magnet films are connected to both ends of the GMR element 57, by which the magnitude of a magnetic field is detected.

In FIG. 8, the GMR element 57 comprises a free layer 53, a conduction layer 54, a pinned layer 55, and an antiferromagnetic layer 56, which are sequentially laminated and combined together. Of course, the constitution of the GMR element 57 is not necessarily limited to the aforementioned constitution shown in FIG. 8. The GMR element 57 includes the pinned layer 55 whose magnetization direction is pinned in a prescribed direction, and the free layer 53 whose magnetization direction varies in response to an external magnetic field. That is, when an external magnetic field is applied, the magnetic sensor 100 presents a resistance in response to the relationship between the magnetization direction of the pinned layer 55 and the magnetization direction of the free layer 53, whereby by measuring the resistance, it is possible to detect the external magnetic field.

In order to accurately detect an external magnetic field whose magnitude is relatively small, the magnetic sensor 100 should maintain the magnetization direction of each segment of the free layer 53 to match a prescribed direction (hereinafter, referred to as an initial direction) in a stable manner when no external magnetic field is applied thereto. In FIG. 8, arrow symbols written in the free layer 53 show the prescribed direction, i.e., the initial direction.

For this reason, the free layer made of a thin film is generally formed in a rectangular shape in plan view, wherein the long side (or longitudinal axis) is forced to match the initial direction, which is called “segment magnetization”, whereby by using the so-called “form anisotropy” in which the magnetization direction substantially matches the longitudinal direction, the magnetization direction of each segment of the free layer 53 is forced to match the initial direction. When the external magnetic field disappears, it is necessary for the magnetization direction of each segment of the free layer 53 to be restored to the initial direction, which should be maintained for a long time in a stable manner. Therefore, the bias magnetic layers 52 made of permanent magnet films are arranged on both ends of the free layer 53 in the longitudinal direction, whereby a certain magnetic field is applied to the free layer 53 in the initial direction. This is disclosed in Japanese Patent Application Publication No. H10-91920 (see paragraph [0004]), for example.

The formation of the bias magnetic layer 52, which is used to establish the segment magnetization with respect to each segment of the free layer 53, is continuously performed so as to produce a required magnitude of a bias magnetic field (i.e., coercive force and residual magnetism) after an embedded layer 51 made of a non-magnetic film for mounting the bias magnetic layer 52 is produced with a prescribed thickness. In order to control the bias magnetic field, it is necessary to adequately change the film composition adapted to the bias magnetic layer 52 or to change the thickness of the bias magnetic layer 52. This is disclosed in Japanese Patent Application Publication No. 2000-137906 (see paragraph [0272]), for example. FIG. 7 is a graph showing an example of a magnetic hysteresis loop adapted to the bias magnetic layer 52, wherein coercive force Hc is set with respect to a horizontal axis, and residual magnetism Mr is set with respect to a vertical axis.

Normally, when a sputtering method is performed to form the bias magnetic layer 52, it is necessary to change the composition of a target, thus changing the film composition thereof. Herein, a vacuum chamber incorporating the target is temporarily opened to the atmospheric air so as to change the target; then, the chamber is decompressed to a certain degree of vacuum that allows the film formation to progress therein. This requires a relatively large amount of work, cost, and time, which increases the overall manufacturing cost. When the free layer and pinned layer are changed in structures, it is necessary to change a bias magnetic field in response to the magnetic property, whereby it is necessary to change the composition of the target at each time when the bias magnetic field is changed in structure.

In the manufacture conditioning, the composition of the target differs from the film composition of the bias magnetic layer 52 so that an unwanted deviation may occur in the composition of the target. For this reason, it is necessary to provide various types of targets having different compositions in order to determine the prescribed composition of the target. Even when the composition of the target is determined, an erosion form occurring in the target may vary in time as the used time period thereof becomes longer; therefore, the substantial used time of the target should be limited to a relatively short time period because the film composition may be easily varied.

By changing the thickness of the bias magnetic layer 52, it may be possible to change the magnetic property of the bias magnetic layer 52, which is represented by two factors, i.e., the coercive force Hc and the residual magnetism Mr shown in FIG. 7. However, no conventional technology can control each of the coercive force Hc and the residual magnetism Mr independently. Generally speaking, there is a tendency in which when the thickness of the bias magnetic layer 52 is increased, the coercive force is decreased while the residual magnetism is increased. For this reason, when one factor of the magnetic property is forced to match a desired value, the other factor may be sacrificed. For example, it becomes difficult to magnetize the bias magnetic layer in the manufacturing process when the coercive force of the bias magnetic layer is relatively large, whereas when the coercive force is relatively small, the magnetic sensor may be easily influenced by a disturbance magnetic field. In addition, the pinned layer may be easily deteriorated over a long period of use when the residual magnetism of the bias magnetic layer is relatively large, whereas when the residual magnetism is relatively small, it becomes difficult to perform segment magnetization with respect to the free layer.

### SUMMARY OF THE INVENTION

It is an object of the invention to provide a magnetic sensor and a manufacturing method therefor, wherein it is possible to obtain desired magnetoresistive (MR) characteristics that can be maintained for long periods in a stable manner, regardless of a disturbance magnetic field.

It is another object of the invention to provide a magnetic sensor and a manufacturing method therefor, wherein it is possible to freely change the combination of coercive force and residual magnetism, which represent the magnetic property of a bias magnetic layer, without changing the composition of a target used for producing the bias magnetic layer.

This invention is directed to a magnetic sensor comprising a spin-valve type magnetoresistive element that is arranged on a substrate, wherein bias magnetic layers composed of permanent magnet films are connected with both ends of the magnetoresistive element, by which the magnitude of a magnetic field is detected. Herein, the bias magnetic layer is formed on an embedded layer that is composed of a non-magnetic material and that has the laminated structure in which a thick first layer and a thin second layer are sequentially subjected to deposition.

Due to the laminated structure of the embedded layer for mounting the bias magnetic layer, it is possible to control the coercive force of the bias magnetic layer in a broad range by adjusting the thickness of the second layer while the thickness of the bias magnetic layer is maintained at a certain value in order to provide prescribed residual magnetism. That is, the magnetic sensor of this invention has the bias magnetic layer that allows the coercive force and residual magnetism to be independently controlled and to be freely selected in combination without substantially changing the composition of a target, which is used for the film formation. This allows both of the coercive force and residual magnetism to be maintained at prescribed values, respectively. Unlike the conventional magnetic sensor, the magnetic sensor of this invention does not necessarily sacrifice one of two factors (i.e., coercive force and residual magnetism) of magnetic characteristics when the other is set to a desired value.

In the magnetic sensor of this invention, the bias magnetic layer is hardly influenced by a disturbance magnetic field; therefore, it is possible to maintain the coercive force of the bias magnetic layer in a range that does not cause difficulties in magnetizing the bias magnetic layer; it is possible for the pinned layer of the GMR element not to be easily deteriorated over a long period of use; and it is possible to control the residual magnetism of the bias magnetic layer in a range that does not cause difficulties in performing segment magnetization on the free layer of the GMR element. By adequately controlling the thickness of the second layer of the embedded layer, it is possible to eliminate all the problems that the conventional technology suffers when exchanging a target for use in the formation of the bias magnetic layer. That is, the manufacturing method of this invention is preferably applied to mass production of magnetic sensors because it demonstrates remarkable cost-saving effects in manufacturing.

As the material for use in the embedded layer, it is preferable to use Cr or a Cr alloy, for example. When the thickness of the second layer of the embedded layer is less than 2 nm, it is difficult to form the second layer having the uniform thickness. In that case, it may be possible to omit the second layer, whereas no substantial change can be observed with respect to magnetic characteristics of the bias magnetic layer even though the embedded layer comprises the first layer only. In addition, the coercive force of the bias magnetic layer is not substantially increased even when the second layer of 10 nm or more is formed in the embedded layer. That is, it is preferable that the thickness of the second layer range from 2 nm to 10 nm.

In the aforementioned magnetic sensor, the first and second layers are composed of crystal grains forming columnar structures, which are mutually discontinuous, wherein it is preferable that the average diameter of crystal grains forming the first layer is larger than the average diameter of crystal grains forming the second layer. In addition, it is preferable that the first layer composed of crystal grains forms a columnar structure, and the second layer has an amorphous structure.

The embedded layer for mounting the bias magnetic layer has a double-layered structure in such a way that the second layer is formed after the formation of the first layer. The first layer has a relatively large thickness that allows crystal grains to grow at a high pace, thus forming the columnar structure. In contrast, the second layer has a relatively small thickness that allows crystal grains thereof to form a relatively fine structure, or it may be stopped in the initial stage of crystal growth so as to form a non-crystal structure or an amorphous structure. Sizes of crystal grains and their structures can be observed using a scanning electron microscope (SEM) or a transmission electron microscope (TEM), wherein it is possible to measure the average diameter of crystal grains by use of the known measurement method(s) allowing visual confirmation of crystal grains through image processing. The magnetic sensor of this invention is designed such that the bias magnetic layer is formed on the second layer having the aforementioned structure, wherein the embedded layer is designed such that the second layer is composed of crystal grains whose sizes are relatively small compared with sizes of crystal grains forming the first layer. This allows the bias magnetic layer to grow on the second layer so that magnetic characteristics of the bias magnetic layer varies in proportion to sizes of crystal grains forming the second layer. Thus, even though the free layer and pinned layer of the GMR element are changed in specifications and dimensions, it is possible to produce a magnetic sensor that is not influenced by a disturbance magnetic field and that can be maintained in desired MR characteristics in the long time in a stable manner.

The manufacturing method of this invention adapted to the aforementioned magnetic sensor comprises two steps, namely, step A in which a thick first layer is deposited, and then, a thin second layer is continuously deposited on the first layer so as to form the embedded layer for mounting the bias magnetic layer, and step B in which the bias magnetic layer is deposited on the second layer of the embedded layer.

In the above, step A is contributed to “continuous” formation or deposition realized on the embedded layer, thus avoiding intervention of impurities and oxygen on the interface between the first and second layers. This allows crystal grain growth with respect to the “extremely thin” second layer so as to realize uniform crystal orientation. In step B, the bias magnetic layer is deposited on the embedded layer having the double-layered structure, wherein it is possible for the bias magnetic layer to have extremely high crystal orientation.

Thus, it is possible to control the coercive force of the bias magnetic layer in a broad range by merely adjusting the thickness of the second layer while the thickness of the bias magnetic layer is maintained at a prescribed value in order to provide prescribed residual magnetism.

In particular, it is preferable for step A to perform deposition of the second layer on the first layer before an oxide film is formed on the first layer. Thus, even when the second layer is very thin, it is possible to maintain high crystal orientation in a stable manner. A sputtering method is preferably used for the deposition of the embedded layer and the bias magnetic layer. This is because it has an advantage in that high adhesion can be secured even in the formation of an extremely thin film.

Due to the sequential and continuous deposition of the first and second layers forming the embedded layer for mounting the bias magnetic layer, it is possible to independently control the coercive force and residual magnetism of the bias magnetic layer by changing the thickness of the second layer and the thickness of the bias magnetic layer respectively. Thus, it is possible to produce the magnetic sensor that has a strong resistance to a disturbance magnetic field and that demonstrates a highly stable magnetoresistive effect over a long period of use.

In the manufacturing method of this invention, it is possible to produce magnetic sensors each having the aforementioned characteristics in a stable manner by adequately changing the thickness of the second layer and the thickness of the bias magnetic layer. This eliminates the necessity of performing exchanging operation of a target (i.e., a base material for the film formation), which is required in the conventional manufacturing method in order to change the composition of the bias magnetic layer. This realizes a remarkable reduction of the manufacturing time, which is conventionally increased due to the exchanging operation of a target. Thus, this invention can demonstrate cost-saving effects in manufacturing because it brings remarkable reductions in the manufacturing time and working labor.

### BRIEF DESCRIPTION OF THE DRAWINGS

These and other objects, aspects, and embodiments of the present invention will be described in more detail with reference to the following drawings, in which:

FIG. 1 is a cross-sectional view showing the structure of a magnetic sensor in accordance with a preferred embodiment of the invention;

FIG. 2 is a cross-sectional view showing the structure in which a bias magnetic layer is formed on an embedded layer comprising two layers, which are formed with continuous deposition;

FIG. 3 is a graph showing the relationship between the coercive force and the thickness of the bias magnetic layer in connection with various values of the thickness of the embedded layer in the structure of FIG. 2;

FIG. 4 is a graph showing the relationship between the thickness of the bias magnetic layer and the residual magnetism in the magnetic sensor;

FIG. 5 is a cross-sectional view showing the structure in which a bias magnetic layer is formed on an embedded layer comprising two layers, which are formed with non-continuous deposition;

FIG. 6 is a graph showing the relationship between the coercive force and the thickness of the bias magnetic layer in connection with various values of the thickness of the embedded layer in the structure of FIG. 5;

FIG. 7 is a graph showing a magnetic hysteresis loop adapted to the bias magnetic layer;

FIG. 8 is a cross-sectional view showing the structure of a conventionally known magnetic sensor;

FIG. 9 is a graph showing the time-related dependency for a MR ratio with regard to residual magnetism (Mr);

FIG. 10 diagrammatically shows a first example of the formation of a first layer having a columnar structure and a second layer having a fine structure within an embedded layer; and

FIG. 11 diagrammatically shows a second example of the formation of a first layer having a columnar structure and a second layer having an amorphous structure within an embedded layer.

### DESCRIPTION OF THE PREFERRED EMBODIMENTS

This invention will be described in further detail by way of examples with reference to the accompanying drawings.

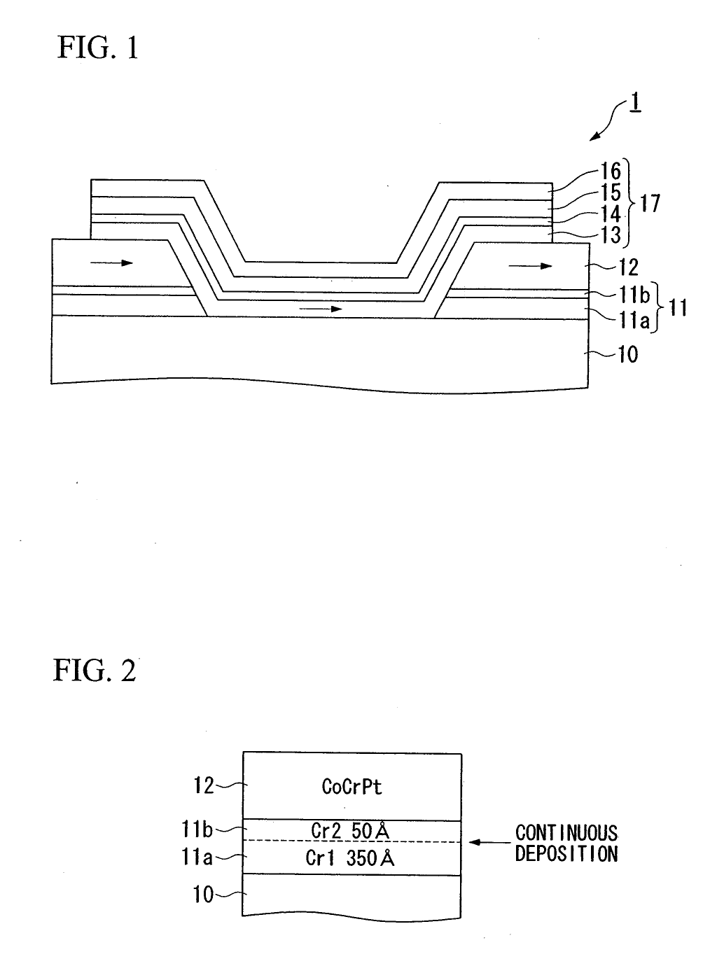

FIG. 1 is a cross-sectional view diagrammatically showing the structure of a magnetic sensor in accordance with a preferred embodiment of the invention.

A magnetic sensor 1 shown in FIG. 1 comprises a spin-valve type GMR element 17 that is arranged on a substrate 10, wherein both ends of the GMR element 17 are connected with bias magnetic layers 12 made of permanent magnet films, by which it is possible to detect the magnitude of an external magnetic field applied thereto. It is preferable for the magnetic sensor 1 to employ the laminated structure shown in FIG. 1 in which a free layer 13, a conduction layer 14, a pinned layer 15, and an antiferromagnetic layer 16 are sequentially laminated and combined together. Of course, the magnetic sensor of this invention does not necessarily employ such a laminated structure as is shown in FIG. 1. The GMR layer 17 is formed in accordance with the known film formation method by use of the known materials, details of which are omitted for the sake of convenience.

FIG. 1 shows a so-called “gull-wing” type structure for use in the magnetic sensor 1 in which the lower surfaces of the both ends of the GMR element 17 strand on the upper surfaces of the bias magnetic layers 12. It is possible for the magnetic sensor of this invention to use other types of structures such as a so-called “abutted junction” type in which the side surfaces of the both ends of the GMR element 17 are brought into contact with the side surfaces of the bias magnetic layers 12, and a so-called “overlay” type in which the lower surfaces of the ends portions of the bias magnetic layers 12 are overlaid onto the upper surfaces of the both ends of the GMR element 17.

FIG. 2 is a cross-sectional view diagrammatically showing the laminated structure adapted to the bias magnetic layer 12 and an embedded layer 11. The bias magnetic layer 12 is arranged on the embedded layer 11, which is composed of a non-magnetic material and which is formed by sequentially laminating a first layer 11a made of a thick film and a second layer 11b made of a thin film. Herein, the thickness of the first layer 11a, the thickness of the second layer 11b, and the thickness of the bias magnetic layer 12 serve as factors for controlling the coercive force and residual magnetism. Specifically, the embedded layer 11 is constituted by a Cr film, and the bias magnetic layer 12 is constituted by a CoCrPt film, for example.

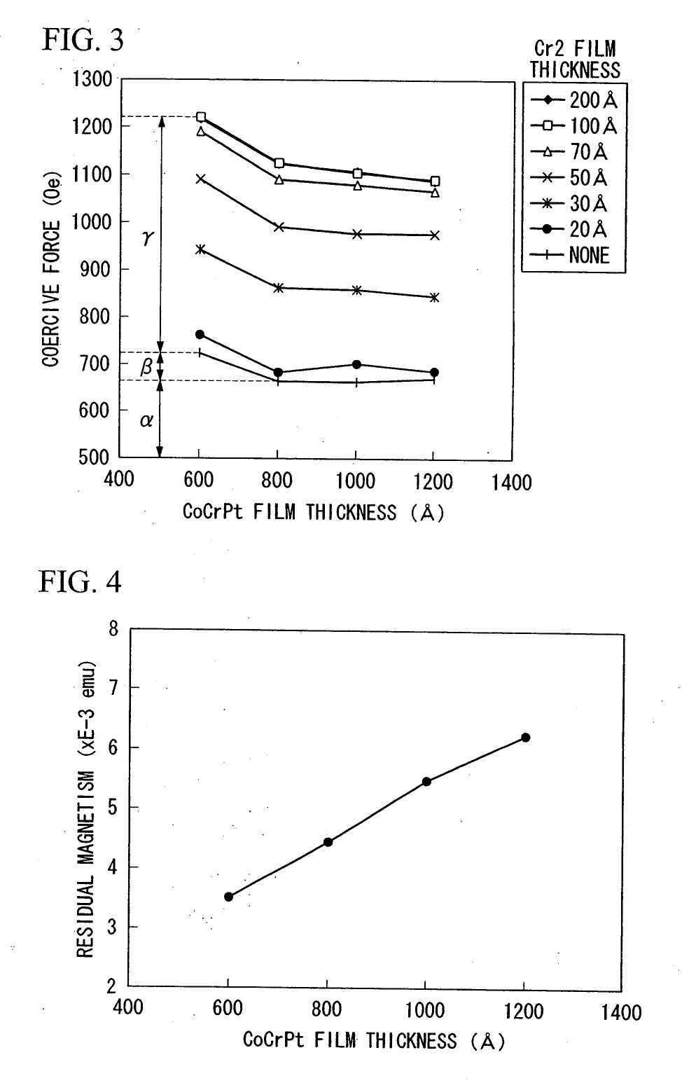

FIG. 3 is a graph showing the relationship between the coercive force and the thickness of the bias magnetic layer 12 that is formed on the embedded layer 11 as shown in FIG. 2. When the “thick” first layer 11a and the “thin” second layer 11b are sequentially laminated to form the embedded layer 11, they must be continuously formed in order to avoid intervention of impurities and oxygen at the interface therebetween; then, the bias magnetic layer 12 is formed on the embedded layer 11. Herein, the sputtering method is used for the formation of the embedded layer 11 and the bias magnetic layer 12. Specifically, the total thickness of the first layer 11a and the second layer 11b is set to 400 Å (or 40 nm), and the graph of FIG. 3 is produced by changing the thickness of the second layer 11b in a range from 0 Å to 200 Å. That is, FIG. 3 shows the dependency of the bias magnetic layer 12 depending on the thickness of the second layer 11b.

According to the graph of FIG. 3, the coercive force can be distributed in three ranges, namely, a basic range a depending on the first layer 11a (i.e., the lower layer of the embedded layer 11), a first variation range β depending on the bias magnetic layer 12, and a second variation range γ depending on the second layer 11b (i.e., the upper layer of the embedded layer 11).

With respect to the basic range α, as long as the thickness of the first layer 11a is 200 Å or more, the coercive force may have a certain value (i.e., 650 Oe) without depending on the thickness of the first layer 11a. With respect to the first variation range β, when the bias magnetic layer 12 is 1000 Å or more, the coercive force tends to be decreased in response to an increase of the thickness of the bias magnetic layer 12. With respect to the second variation range γ, the coercive force tends to be increased when the thickness of the second layer 11b is increased in a range from 20 Å to 100 Å.

FIG. 3 shows various types of results regarding the coercive force in connection with different values of the thickness of the second layer 11b, wherein black-circle symbols indicate results produced with regard to 20 Å thickness; “*” symbols indicate results produced with regard to 30 Å thickness; “x” symbols indicate results produced with regard to 50 Å thickness; triangle symbols indicate results produced with regard to 70 Å thickness; black-square symbols indicate results produced with regard to 100 Å thickness; and black-diamond symbols indicate results produced with regard to 200 Å thickness.

From the results shown in FIG. 3, it is possible to summarize the following points.
(1) By arranging the second layer 11b whose thickness is 20 Å, it is possible to increase the coercive force by 20 Oe to 30 Oe, regardless of the thickness of the bias magnetic layer 12.
(2) When the second layer 11b is designed to have the thickness of 30 Å, it is possible to noticeably increase the coercive force by 200 Oe or so, regardless of the thickness of the bias magnetic layer 12.
(3) When the second layer 11b is designed to have the thickness of 50 Å, it is possible to further increase the coercive force by 150 Oe or so, compared with the coercive force produced using the second layer 11b of the 30 Å thickness.
(4) When the second layer 11b is designed to have the thickness of 70 Å, it is possible to further increase the coercive force by 100 Oe or so, compared with the coercive force produced using the second layer 11b of the 50 Å thickness.
(5) When the second layer 11b is designed to have the thickness of 100 Å, it is possible to further increase the coercive force by 20 Oe to 30 Oe, compared with the coercive force produced using the second layer 11b of the 70 Å thickness.
(6) When the second layer 11b is designed to have the thickness of 200 Å, substantially no increase is recognized with respect to the coercive force, which is substantially identical to the coercive force produced using the second layer 11b of the 100 Å thickness.

Based on the aforementioned results, it is possible to conclude that by controlling the thickness of the second layer 11b in a range from 20 Å to 100 Å (i.e., from 2 nm to 10 nm), it is possible to adequately adjust the coercive force within a range of 500 Oe. In addition, it is possible to detect an increase in the coercive force when the thickness of the bias magnetic layer 12 is 100 Å or less, regardless of the thickness of the second layer 11b. By using such a tendency, it is possible to actualize minor adjustment with respect to the coercive force.

FIG. 4 is a graph showing the relationship between the thickness of the bias magnetic layer 12 (i.e., CoCrPt film) and the residual magnetism. The graph of FIG. 4 clearly indicates that the residual magnetism can be linearly increased by increasing the thickness of the bias magnetic layer 12. This graph is created with respect to the foregoing structure of the magnetic sensor as shown in FIG. 2 in which the embedded layer 11 comprises the first layer 11a whose thickness is 360 Å (or 36 nm) and the second layer 11b whose thickness is 40 Å (or 4 nm), whereas the result of this graph does not depend upon the structure of the embedded layer 11. That is, the same result can be repeatedly produced as long as the embedded layer 11 comprises the first layer 11a of the prescribed thickness without depending upon the existence of the second layer 11b or the thickness of the second layer 11b.

From the aforementioned results, the magnetic sensor 1 of the present embodiment in which in which the bias magnetic layer 12 is formed on the embedded layer 11 having the laminated structure comprising the ‘thick’ first layer 11a and the ‘thin’ second layer 11b is advantageous in that the coercive force can be adjusted in a relatively wide range by adjusting the thickness of the second layer while the thickness of the bias magnetic layer 12 is substantially maintained at a prescribed value in order to produce the prescribed residual magnetism. Therefore, it is possible to produce a variety of combinations of magnetic characteristics (represented by combinations of the coercive force and residual magnetism), which can be applied to magnetoresistive elements, without substantially changing the film composition of the bias magnetic layer.

The aforementioned description is made in the case where the embedded layer 11 is composed of Cr. The same tendency as described in the aforementioned embodiment can be recognized with respect to the other composition of the embedded layer 11, which can be made of a Cr alloy composed of Cr—Mn, Cr—Mo, and Cr—Ta, for example. In addition, the aforementioned description is made in the case where the bias magnetic layer 12 is made of a CoCrPt alloy, whereas the bias magnetic layer 12 does not necessarily depend upon certain film composition as long as it is made of a so-called inter-plane magnetic film composed of a Co alloy that shows inter-plane orientation when arranged on the embedded layer made of a Cr film.

### 1. Control of Residual Magnetism

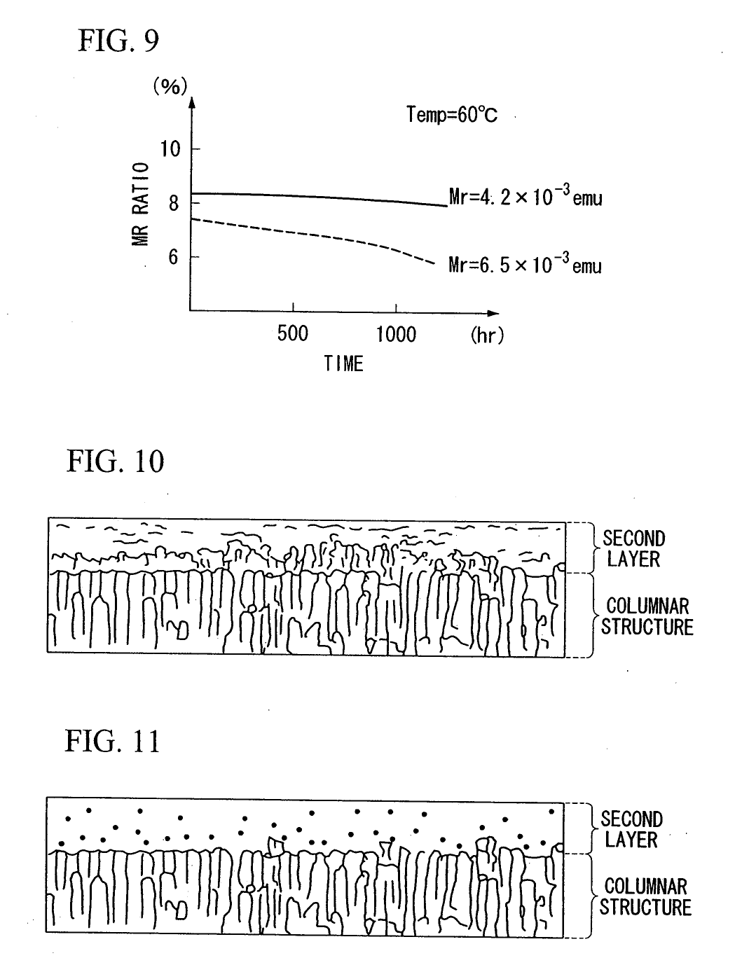

Experimentally, when the residual magnetism is less than 0.0040 emu, the free layer cannot be subjected to segment magnetization; hence, the so-called “spin-valve operation” becomes unstable, which makes it impossible to produce a desired magnetoresistive effect in a stable manner. On the other hand, when the residual magnetism is greater than 0.0055 emu, the free layer may not precisely respond to the external magnetic field, which makes it impossible to produce a relatively large MR ratio and which may eventually cause a reduction in the MR ratio in the long use because it becomes very difficult to maintain the magnetization direction of the fixedly magnetized layer being perpendicular to the magnetization direction of the free layer (see FIG. 9). In order to embrace the residual magnetism within the foregoing range, it is preferable to set the thickness of the bias magnetic layer 12, composed of a CoCrPt alloy, for example, within the range from 800 Å to 900 Å.

### 2. Control of Coercive Force

Normally, in the production of the magnetoresistive element, a magnetization process using a ‘bulk’ permanent magnet is performed in order to align and coordinate all of the magnetization directions of the bias magnetic layers. When the coercive force of the bias magnetic layer is greater than 1100 Oe so that a relatively large magnetic field beyond the coercive force of the permanent magnet is required for the magnetization of small regions of the bias magnetic layer, it is very difficult to magnetize the bias magnetic layer. On the other hand, when the coercive force of the bias magnetic layer is less than 800 Oe, the bias magnetic layer may be easily magnetized with a relatively intense magnetic field applied to the magnetoresistive element, wherein the magnetization direction of the free layer becomes unstable, which makes the spin-valve operation become unstable. In summary, in order to control the coercive force within the aforementioned range from 800 Oe to 1100 Oe, it is necessary to change the thickness of the embedded layer in conformity with the thickness of the bias magnetic layer.

The production method of this invention is adapted to a magnetic sensor comprising a spin-valve type magnetoresistive element that is formed on a substrate so as to detect the magnitude of an external magnetic field, wherein both ends of the magnetoresistive element are connected with bias magnetic layers made of permanent magnet films. Specifically, it comprises step A in which a ‘thick’ first layer is deposited, then, a ‘thin’ second layer is continuously deposited on the first layer so as to form an embedded layer on which the bias magnetic layer is arranged, and step B in which the bias magnetic layer is deposited on the second layer of the embedded layer.

As described above, step A is performed first so as to activate the deposition of the thick first layer, and then, step B is performed so as to continuously deposit the thin second layer on the first layer. FIG. 2 shows the structure in which the bias magnetic layer 12 is further deposited on the embedded layer 11. FIG. 3 shows variations of the coercive force that are produced in the structure of FIG. 2.

In the case of the structure of FIG. 2, the embedded layer 11 comprises the thick first layer 11a and the thin second layer 11b, which are sequentially subjected to deposition in order to avoid the intervention of impurities and oxygen on the interface, and then, the bias magnetic layer 12 is formed on the embedded layer 11. In this case, by adequately changing the thickness of the second layer 11b in the aforementioned range, it is possible to precisely control the coercive force within the range between 700 Oe and 1100 Oe.

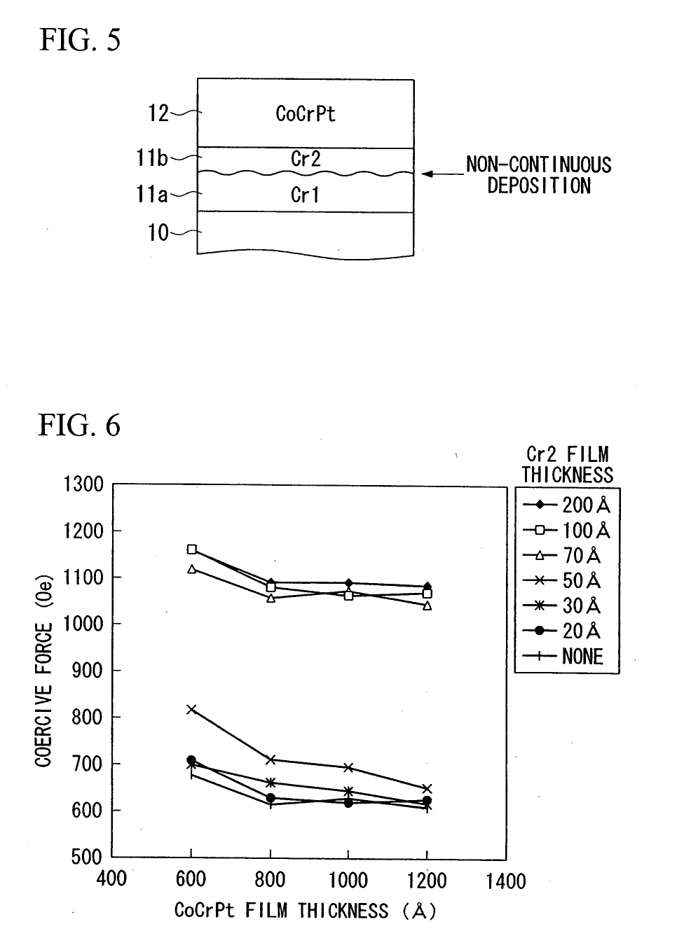

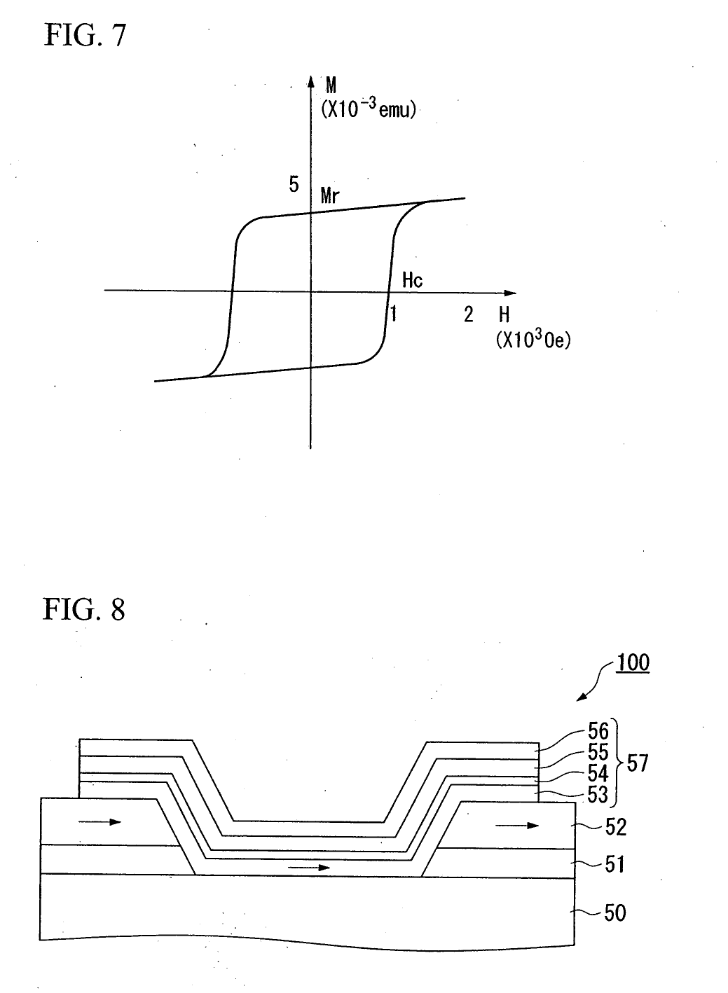

FIG. 5 shows another structure that differs from the aforementioned structure of FIG. 2, in particular, with respect to the formation of an embedded layer 11. That is, step A is performed to deposit a thick first layer 11a, which is exposed to the atmosphere, and then, a thin second layer 11b is deposited on the first layer 11a in a non-continuous manner, which is referred as “non-continuous deposition”. Then, step B is performed to further deposit a bias magnetic layer 12 on the second layer 11b of the embedded layer 11. FIG. 6 shows variations of the coercive force that is produced in the structure of FIG. 5.

Specifically, FIG. 6 shows the relationship between the coercive force and the thickness of the bias magnetic layer 12 that is formed on the embedded layer 11 in the structure of FIG. 5, wherein it also shows the dependency of the bias magnetic layer 12 depending on the thickness of the second layer 11b. The results shown in FIG. 6 are produced in the structure of FIG. 5 in which the first layer 11a and the second layer 11b are sequentially formed with the non-continuous deposition. FIG. 6 does not show the effect of the second layer 11b whose thickness is changed in a range between 20 Å and 30 Å, whereas when the thickness of the second layer 11b is increased to 50 Å, it is possible to increase the coercive force by 50 Oe to 100 Oe. In addition, when the thickness of the second layer 11b exceeds 70 Å, the coercive force must be remarkably increased by 400 Oe or so.

Furthermore, even when the thickness of the second layer 11b is increased by 100 Å to 200 Å, substantially no change can be observed with respect to the coercive force, compared with the coercive force that is produced using the second layer 11b having 70 Å thickness. In summary, FIG. 6 clearly shows that in the structure of FIG. 5 in which the formation (or deposition) is temporarily stopped between the first layer 11a and the second layer 11b in the embedded layer 11, the coercive force does not vary in proportion to the thickness of the second layer 11b, regardless of the provision of the second layer 11b whose thickness is changed in a prescribed range. That is, it is very difficult to precisely control the coercive force in a broad range.

According to this invention, through the comparison between the results of FIG. 3 and the results of FIG. 6, it is strongly recommended that when the double-layered embedded layer for mounting the bias magnetic layer is produced such that the thick first layer is deposited, and then the thin second layer is deposited on the first layer in the step A, the first and second layers should be continuously formed in order to avoid intervention of impurities and oxygen on the interface therebetween. As impurities badly influencing the interface, it is possible to list water content remaining in the internal space of the chamber, adhering matter peeled off from the internal wall of the chamber, and the like.

As described heretofore, this invention provides a magnetic sensor and a manufacturing method therefor in which the magnetic sensor has a relatively strong resistance against a disturbance magnetic field and provides desired MR characteristics that are maintained for a long time in a stable manner. Therefore, the magnetic sensor of this invention is preferably applied to portable electronic devices such as cellphones and navigation systems used in automobiles, which require highly stable characteristics to be maintained even when environmental conditions successively change. In addition, the manufacturing method of this invention is advantageous in that the combination of the coercive force and residual magnetism in the bias magnetic layer can be changed in a flexible manner by merely controlling the film thickness. This contributes to the stable and cost-saving manufacturing for magnetic sensors.

FIGS. 10 and 11 show examples of embedded layers each comprising first and second layers composed of crystal grains, which can be observed using a scanning electron microscope (SEM). In FIG. 10, the first layer forms a columnar structure, and the second layer forms a fine structure. In FIG. 11, the first layer forms a columnar structure, and the second layer forms an amorphous structure.

As this invention may be embodied in several forms without departing from the spirit or essential characteristics thereof, the present embodiments are therefore illustrative and not restrictive, since the scope of the invention is defined by the appended claims rather than by the description preceding them, and all changes that fall within metes and bounds of the claims, or equivalents of such metes and bounds are therefore intended to be embraced by the claims.

What is claimed is:

1. A manufacturing method for manufacturing a magnetic sensor in which a bias magnetic layer made of a permanent magnet film is connected with both ends of a magnetoresistive element of a spin-valve type, which is arranged on a substrate and by which magnitude of a magnetic field is detected, said manufacturing method comprising the steps of:
depositing a thick first layer, and then continuously depositing a thin second layer on the first layer, thus forming an embedded layer for mounting the bias magnetic layer; and
further depositing the bias magnetic layer on the second layer of the embedded layer.

2. The manufacturing method for a magnetic sensor according to claim 1, wherein the second layer is deposited on the first layer before an oxide film is formed on the first layer.

3. The manufacturing method for a magnetic sensor according to claim 1, wherein a sputtering method is used for deposition of the embedded layer and for deposition of the bias magnetic layer.

4. The manufacturing method for a magnetic sensor according to claim 1, wherein the embedded layer is composed of Cr or a Cr alloy.

5. The manufacturing method for a magnetic sensor according to claim 1, wherein the bias magnetic layer is composed of a CoCrPt alloy, and thickness thereof ranges from 800 Å to 900 Å.

6. The manufacturing method for a magnetic sensor according to claim 1, wherein the thickness of the first layer ranges from 2 nm to 10 nm.

7. The manufacturing method for a magnetic sensor according to claim 1, wherein the first layer is composed of crystal grains forming a columnar structure, and the second layer is composed of crystal grains smaller than the crystal grains of the first layer so as to form a fine structure or an amorphous structure.
